(19) United States
(12) Patent Application Publication
(10) Pub. No.: US 2018/0318842 A1
(43) Pub. Date: Nov. 8, 2018

(54) METHOD AND APPARATUS FOR SEPARATION AND SIZE REDUCTION OF NOBLE METAL CONTAINING SOURCES

(71) Applicant: EAUTERRE CONSULTING, LLC, Bethel, CT (US)

(72) Inventor: Michael B. KORZENSKI, Bethel, CT (US)

(21) Appl. No.: 15/773,063

(22) PCT Filed: Nov. 8, 2016
(86) PCT No.: PCT/US2016/060967

§ 371 Date: May 2, 2018

Related U.S. Application Data
(60) Provisional application No. 62/252,638, filed on Nov. 9, 2015.

(51) Int. Cl. B02C 17/18; B02C 17/04; C22B 1/00; C22B 5/02; C22B 7/00; C22B 11/02; B09B 3/00

(52) U.S. Cl. CPC B02C 17/1835; B02C 17/04; B02C 17/1815; C22B 1/005; H05K 2203/178; C22B 7/001; C22B 11/025; B09B 3/0083; C22B 5/02

(57) ABSTRACT

The invention discloses improvements and additional uses of thermo-mechanical processes using a rotary kiln for the separation of parts from a device that are held together by various means such as solder, epoxies, glues, and/or any other thermally degradable adhesives or underfills, and which is suitable for material size reduction via thermal decomposition of encapsulant materials such as integrated circuit casings or thermally degradable materials such as carbon-based hydro processing catalysts. The invention includes further sorting the materials according to predetermined size either in-situ or in series using a meshed vibrating table downstream of the rotary kiln. These devices can include, but not limited to, printed circuit boards, catalysts, solar panels, and the like.

This application claims the benefit of U.S. provisional application No. 62/252,638 filed Nov. 9, 2015, the entire content of which is expressly incorporated herein by reference thereto.

### TECHNICAL FIELD

The present invention relates to a method and apparatus incorporating a thermo-mechanical process using a rotary kiln for separation of parts or products held together by various adhesion means such as solder, epoxies, glues, and any other thermally degradable adhesives, in addition to size reduction of metal-bearing sources, including but not limited, to printed circuit boards, catalysts, and solar panels. Metals, and more importantly nobles-metals, present in the original source material, comprise a small percent of the overall source weight, making their removal from said source more difficult. In consequence of organic substances removal, concentration of metals in the inorganic phase is increased, thus making the subsequent operations oriented to metal recovery more effective.

### BACKGROUND AND PRIOR ART

The recovery of electronic components from waste electronics, specifically printed wire boards, has been studied extensively over the years due to the need for removal of high value, noble-metal containing components from the printed wire board prior to downstream processing. Separation is critical to create a noble-metal concentrate for further recovery of said noble metals. While IC physical constructions and applications may vary widely, the role of and composition of IC encapsulants are fewer in number. The encapsulant has the fundamental functions to protect the die from physical damage, providing a thermal path away from the die, to name just a few. It is well known that the highest concentration of noble metals in electronic waste resides underneath and protected by said encapsulants, this breaking down the encapsulant to expose these noble metals is critical to enable complete recovery of both noble and non-noble metals.

Zhou et al. (J. Haz. Mat. 175, pp. 823-828 (2010)) describes a process of “centrifugal separation plus vacuum pyrolysis” for recycling printed circuit boards. The article describes experiments performed in a closed reaction vessel, in which diesel oil is used as a heating medium for printed circuit boards. However, as the flash point of the diesel oil is 62° C. and its auto ignition temperature is 210° C. (both of which are lower than the temperature required to melt lead-free solder), diesel oil is unlikely to be considered to be a safe heating medium for lead-free solder melting applications and many other solder melting applications. It should also be considered that the recovery of electronic components is not the final purpose of the process described in the Zhou article, but a first step of a two-stage recycling process, in which the recovered electronic components are pyrolyzed. The electronic components would not be recovered in working condition in such a process.

U.S. Patent Application Publication No. 2010/0223775 describes a method for dismounting through-hole electronic devices where the front surface of a printed circuit board is exposed to a fluorinated inert liquid so that the electronic device is dipped in that liquid and heated in a heating bath. The solder in the through-hole melts using the heat transferred from the electronic device. The majority of fluorinated liquids have a boiling point in the range of 30−215° C., and a flash point which is lower than the temperature needed to melt the solder which can create safety concerns. Furthermore, fluorinated liquids do not represent an environmentally friendly choice as they have an ability to emit gaseous hydrogen fluoride at high temperatures (>20° C.).

U.S. Pat. No. 7,666,321 describes a method for decapsulating a package consisting of a chip, a heat sink, a plurality of solder bumps, a substrate, an underfill, and a plurality of solder balls. The process includes: removing the heat sink, removing the substrate together with the solder balls, performing a dry etching process to remove a portion of the underfill, performing a wet etching process to remove the remaining portion of the underfill, performing a thermal process to melt the solder bumps and performing a solder bump removal process. The dry etching process includes a reactive ion etching process and the wet etching process is performed with the use of fuming nitric acid at 60-100° C. Also, the use of hot fuming nitric acid makes the process unsafe in many cases and can lead to the damage of electronic components.

U.S. Patent Application Publication No. 2014/0217157 describes a systems and method for the removal of electronic chips and other components from printed circuit boards using liquid heat media. The systems and methods described can be used to remove solder, electronic chips and/or other electronic components from printed circuit boards. The electronic components separated from the printed circuit boards can be at least partially separated according to size and density. However, the use of liquid heat transfer liquids for such application result in the high use of rinse water for cleaning the separated parts, and the need for separating the carry over heat transfer liquid from the rinse water, making this process less environmentally friendly. In addition, the need for multiple liquid immersion tanks makes the process too complex and limited to small scale, thus not a viable option for large scale processing. Moreover, the process requires manual insertion of one printed circuit board at a time, which would not be acceptable for high volume processing where thousands of printed circuit boards per hour is required. For many recycling operations, a goal would be to provide fast recovery of all the electronic components in a manner that allows for processing of very large volumes, e.g. several tons per hour, and in doing so in an environmentally benign manner.

### SUMMARY OF THE INVENTION

The invention relates to a method for processing electronic waste material that includes electronic components having parts held thereon by a binding source comprising one or more of a solder, paste, adhesive or encapsulant, wherein the method comprises: tumbling the electronic waste material in a chamber that is arranged to advance the material therein; heating the electronic waste material in the chamber at a temperature sufficient to separate the parts from the components; and providing size reduction of the separated parts to facilitate further processing. The electronic waste includes products such as printed circuit boards, catalysts and solar panels and the binding source is typically any one of a number of adhesives, glues, cements, mucilage, pastes, carbon, solders or organic resins such as epoxies or polyesters.

The chamber is heated to a temperature in the range of 100° C. to 1500° C. to soften or decompose the binding source, and preferably in the range of 100° C. to 600° C. The chamber can be employed in essentially any applicable size, shape and length for continuous or batch processing of the waste material. Advantageously, the chamber is rotated to facilitate tumbling of the waste material therein; and the chamber is tilted at an angle preferably of 1 to 30 degrees to allow the tumbling electronic waste material to advance from one end of the chamber where it is initially introduced to the other end where processed material exits the chamber.

The chamber can be provided with one or more internal members configured, dimensioned and oriented to facilitate tumbling of the electronic waste material in the chamber or advancement of the material through the chamber. The member or members can be configured as a helical unit to create a corkscrew effect to aid in the transport and separation of the device parts. Also, the interior wall of the chamber can include a continuous and/or discrete and/or segmented fin running down at least a portion of the wall, or fins running parallel or perpendicular to the chamber to create or enhance the tumbling action of the waste material for improved mixing and processing of the parts, devices or materials to be separated or size reduced.

The size of the processed material can be reduced as it exits the chamber by ball milling, hammer milling or any other mechanical technique that avoids heat generation during size reduction. Alternatively, or additionally, solid, hollow, and/or porous milling media of any geometric shape can be provided in the chamber in an amount sufficient to provide or facilitate comminution and separation of the waste material. Typically, the milling material has a hardness that is greater than that of the waste material and is constructed of ceramics, steels or similar materials.

The method further comprises sorting the separated parts. This can be achieved in the chamber by passing the separated parts through a perforated tube located within an outer tube in the chamber, wherein the perforations of the inner tube are configured to allow smaller sized parts to pass therethough to provide size sorting of parts before they exit the chamber. It is also possible to sort the separated parts after or as they exit the chamber by providing a vibrating mesh screen that receives the processed material that is exiting the chamber in order to soft that material into various size fractions.

The size reduction of the parts is conveniently achieved by thermally decomposing organic and/or inorganic compositions of the electronic waste material. For this, the temperature of the chamber is set sufficiently high to thermally decompose the organic components. These components are typically encapsulants or thermosetting or thermoplastic materials, including but not limited to, epoxies, polyimides, silicones, silica gel, polyurethanes, cyclobutenes, polyphenylene sulfides, liquid crystal polyesters and derivatives and combinations thereof. The parts to be thermally decomposed can also include a polymer-encapsulated microelectronic unit. Thermal destruction of these material results in a size reduction of the parts. Advantageously, the separation of parts from the components is performed in series or in parallel with the thermal decomposition and size reduction of such parts.

The methods of the invention also facilitate recovering metals from the thermally decomposed material. If desired, the recovered metals can be subjected to additional purification processes. For example, the separated parts can be subjected to a liquid or gaseous chemical process for recovering noble and/or non-noble metals. Alternatively, metals or noble metals can be recovered by subjecting the parts to thermal energy combined with an oxidative gas such as air, oxygen or ozone, to aid in decomposition of the organic materials and obtain metal oxides, followed by subjecting the metal oxides to thermal energy combined with a reductive gas such as hydrogen, forming gas, argon/hydrogen mixtures to reduce the metal oxides to pure metals.

The chamber is preferably a rotary kiln that is tilted and rotated to advance the electronic waste material therethrough its entry at one end to an exit at the other end for processing of the electronic waste material therein. The kiln preferably includes an oxidation zone extending from the exit operatively associated with a device that provides an oxidizing agent into the oxidation zone for contacting and oxidizing the processed material that is advancing through the oxidation zone. The kiln may further includes a reduction zone extending from the oxidation zone in operative association with a device that provides a reducing agent into the reduction zone for contacting and reducing the processed material advancing through the reduction zone. The oxidation and/or reduction zones are heated.

Other advantages and novel features of the present invention will become apparent from the following detailed description of various non-limiting embodiments of the invention when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present invention will be described by way of example with reference to the accompanying figures, which are schematic and are not intended to be drawn to scale. For purposes of clarity, not every component is labeled in every figure, nor is every component of each embodiment of the invention shown where illustration is not necessary to allow those of ordinary skill in the art to understand the invention.

FIG. 1 is a schematic illustration of a rotary kiln system and process used for the thermo-mechanical parts separations and size reduction of various metal-bearing sources.

FIG. 2 is a flow diagram of a thermo-mechanical system and process for separation, sorting and size reduction of a mixed-metal-bearing source.

FIGS. 3A and 3B are schematic top-down (3A) and side view (3B) illustrations of a single rotary tube used inside a rotary kiln according to the present invention.

FIGS. 4A and 4B are schematic top-down (4A) and side view (4B) illustrations of a double rotary tube used inside a rotary kiln according to the present invention, used for sorting in-situ parts and/or devices.

### DETAILED DESCRIPTION AND PREFERRED EMBODIMENTS THEREOF

As defined herein, “binding source” corresponds to any substance applied to one surface, or both surfaces, of two separate items that binds them together. This includes adhesives, solders and the like.

As defined herein, comminution, or comminuted, corresponds to the reduction of solid materials from one average particle size to a smaller average particle size, by crushing, grinding, milling, cutting, vibrating, burning, pyrolysis, thermal decomposition, melting or other processes.

As defined herein, “device” corresponds to an object made for a particular purpose, especially a mechanical or electrical one, including but not limited to, printed circuit boards, solar panels and catalysts.

As defined herein, “material” corresponds to any part, device, product, feedstock or multi-component source, or combinations thereof.

As defined herein, “metal-bearing source” corresponds to any material possessing intrinsic metal value, whether a single metal or multitude of metals.

As defined herein, “noble-metal” corresponds to comprises ruthenium, rhodium, palladium, silver, osmium, iridium, platinum, and gold.

As defined herein, “part” corresponds to a portion or division of a whole that is a separate or distinct, piece, fragment, fraction, or section.

As defined herein, “rotary kiln” corresponds to any rotating pyroprocessing device used to raise materials to elevated temperatures under various atmospheres in a continuous and/or batch process.

As defined herein, “separated” corresponds to any method that causes parts and/or devices to detach, move or be apart, including but not limited to, desoldering, to yield a multitude of materials with smaller size than the original material.

As defined herein, “size reduction” corresponds to any method that reduces the size of a material, to yield a multitude of materials with smaller size or larger surface area than the original material, including but not limited to, by crushing, grinding, milling, cutting, vibrating, burning, pyrolysis, thermal decomposition, melting or other processes.

As defined herein, “sorting” corresponds to any process of arranging items systematically, either by arranging items in a sequence ordered by some criterion; or categorizing and grouping items with similar properties.

As defined herein, “thermal decomposition” and/or “thermally decompose” corresponds to any chemical decomposition caused by heat, wherein heat is required to break chemical bonds in the compound undergoing decomposition.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary.

In particular, the invention relates to the use of rotary kilns for separation of parts from electronic waste material that includes devices such as printed circuit boards, solar panels and catalysts) along with a size reduction of the separated parts. As the electronic waste material includes various noble metal bearing sources, the invention facilitates recovery of noble metals from the separated parts, whether from conventional wet chemical processes or by sequential thermal processing using oxidative gases and then reductive gases.

Rotary kilns and rotary dryers have been widely used over the years for pyro processing of materials such as ceramics, cements and metal alloys. The kiln is a cylindrical vessel, slightly inclined to the horizontal, which is rotated slowly about its axis as the material to be processed is fed into the upper end of the cylinder. When the kiln is rotating, a series of internal fins will lift the material by lining the inner wall of the dryer. When the material reaches certain height to roll the fins back, it will be fall back to the bottom of the kiln, then passing through the hot gas stream as it falls. As the kiln rotates, material gradually moves down towards the lower end, and may undergo a certain amount of stirring and mixing. Hot gases pass along the kiln, sometimes in the same direction as the process material (co-current), but usually in the opposite direction (counter-current). Feed gases may be generated by an external source and used to perform a certain function such as oxidation or reduction of the source material.

The use of rotary kilns for parts separation wherein said parts are adhered together using solder, paste, epoxies or any other type of adhesive, in addition to size reduction of a portion of said parts by thermal oxidation, are generally described herein. Thus the simultaneous removal and size reduction of electronic chips and components from printed circuit boards using a low temperature, oxidizing environment with optional milling media in a rotary style kiln and associated systems and apparatus, are also described. The subject matter of the present invention involves, in some cases, interrelated products, alternative solutions to a particular problem, and/or a plurality of different uses of one or more systems and/or articles.

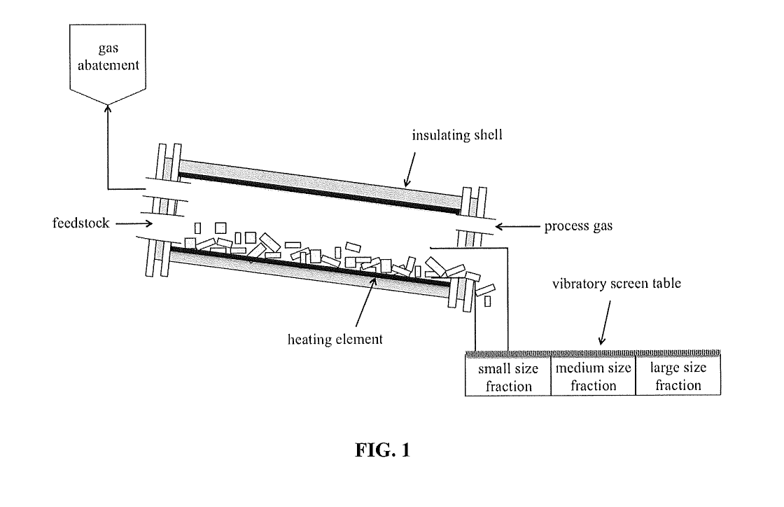

Systems and methods for the removal of parts and other components from devices using thermo-mechanical energy are generally depicted in FIG. 1, which shows the basic arrangement of equipment components. The rotary kiln has a heating element for heating the feedstock that is introduced into the kiln shell. The shell is insulated to conserve the heat that is applied to the feedstock. A process gas is introduced to flow countercurrently to the feedstock and to assist in deteriorating the feedstock therein. Process gas is removed at the end of the kiln where the feedstock enters and is sent to a gas abatement system. The processed feedstock exits the kiln onto a vibratory screen table where it is separated into small, medium or large size fractions which then can be subject to further processing. The systems and methods described herein can be used to remove, melt, soften and/or decompose solder, paste and/or adhesive compounds designed to hold said parts to a device. In certain embodiments, an additional rotary kiln may be used to remove and/or decompose more thermally stable parts and/or adhesives. In certain embodiments, the parts separated from the device may be sorted according to size and/or density.

One aspect of the invention relates to a process for the removal of components or part attached to a surface of a device with solder, paste, and/or adhesive. In some embodiments, the process comprises subjecting the device to thermal energy within a rotary kiln at a temperature higher than the melting temperature of the paste, and/or adhesive such that the paste, and/or adhesive is melted, softened and/or thermally decomposed, resulting in separation of the components or parts from the device. In some embodiments, the process comprises transporting at least a portion of the parts and device out of the vessel, and recycling at least a portion of the thermal energy to the rotary kiln.

In certain embodiments, the process comprises subjecting the device to thermal energy within a rotary kiln in a first heating zone within a rotary kiln at a first temperature that is higher than the melting temperature of the paste, and/or adhesive such that the paste, and/or adhesive is melted, softened and/or thermally decomposed to create separation of parts from a device, and transporting at least a portion of the parts and device out of the vessel, then subjecting the parts and/or device to thermal energy within a second rotary kiln at a second temperature that is higher than the decomposition temperature of the more thermally stable parts or device, and transporting at least a portion of the parts and device out of the second rotary kiln as a size reduced part and/or device.

According to a preferred embodiment, a method is described for desoldering of electronic components from the surface of printed circuit boards, such as motherboards, TV boards, RAM sticks, SCSI cards, cell phone boards, network cards, video cards, and the like, by removal of electronic chips, plastic connectors, capacitors, transistors, resistors, and/or other types of electronic devices, which have been attached to the surface of printed circuit boards with the solder, by melting or softening the solder using thermo-mechanical energy provided in a rotary kiln and optionally applying an external force in order to separate the electronic components from printed circuit boards.

The recovered electronic components can be further re-used in the manufacture of new products or as a source of metals. Electronic components represent 5-20% of the weight of a typical mobile phone printed wire board, while the remaining 80-95% of the weight is attributable to the bare board. Substantially all of the precious metals will be concentrated in 5-20% of the board's weight after removal of the electronic components. Accordingly, the method for recovery of electronic components from printed circuit boards can be part of a method for the concentration of precious metals in printed circuit board recycling, in some embodiments.

Additional embodiments relate to the development of a method for the detachment of electronic components from the surface of printed circuit boards by melting the solder, whereby the electronic components are liberated from the bare boards, and, in some embodiments, both the bare boards and the electronic components can be further separately treated for non-noble and/or noble metals recovery.

Certain embodiments are related to a method for concentrating precious metals, whereby printed circuit boards serve as the input material and the recovered electronic components serve as the material in which precious metals are present in a concentrated form.

Some embodiments are related to a method for the recovery of electronic components in a substantially undamaged and working condition.

Certain embodiments are related to a high capacity and economically efficient process, which can be applied for recycling any type of printed circuit board and/or for recovery of working electronic components, for example, attached to the surface of printed circuit boards with the solder using surface mount, through-hole, ball grid array, flip-chip, other known types of connections.

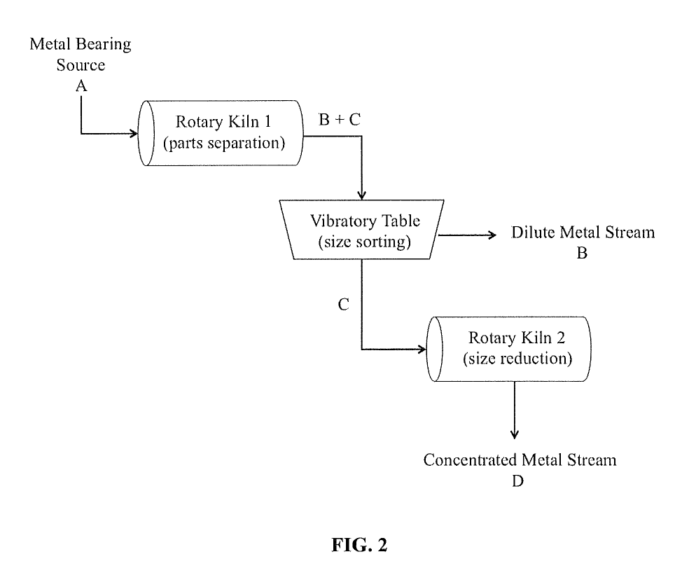

In certain embodiments, the printed wire boards may be subjected to thermo-mechanical energy in a first rotary kiln at a first temperature to remove, melt, and/or soften solder, glues and/or any adhesive to separate parts from a device, and subjected to thermo-mechanical energy in a second rotary kiln at a second temperature that is higher than the decomposition temperature of a thermoplastic encapsulant such that the thermoplastic material is thermally decomposed. For example, referring to the system of FIG. 2, in certain embodiments, devices subjected to thermo-mechanical energy in a first rotary kiln at a first temperature to separate parts from a device, and transporting separated parts and devices along a downward pathway to the exit of the first rotary kiln. In some embodiments, the separated parts and devices may be subsequently subjected to thermo-mechanical energy in a second rotary kiln at a second temperature to thermally decompose. The separation of the parts from the devices includes desoldering as the temperatures in the kiln(s) will soften the solder that hold integrated circuits and other components to a printed wire boards to facilitate separation and removal.

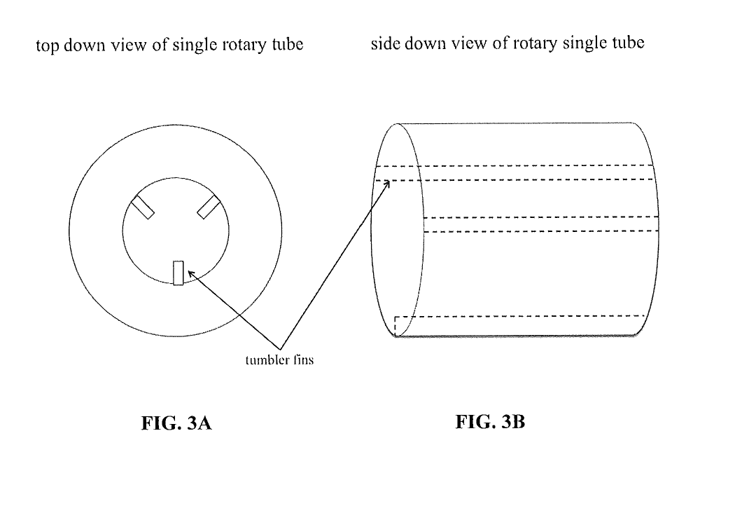

In certain embodiments, parts detachment can be enhanced from the surfaces of devices via any suitable mechanism, such as, for example, forces due to rolling, rotation, shearing, and/or blowing. This can be done by providing internal structures in the chamber, such as baffles or members that assist in tumbling the waste material as the chamber is rotated. For example, tumbler fins are shown in FIGS. 3A and 3B.

In some embodiments, after the parts have been removed from the device, the detached parts and device can be separated according to size and/or density. In certain embodiments, after the parts have been separated from the device according to size and/or density, the parts can be sorted according to size and/or density, and, in certain embodiments, sent for further treatment. In certain embodiments, such separations may be used to group the parts into two or more streams such that the parts within each stream have similar material content, for example, metal type, such that desired concentrates are obtained.

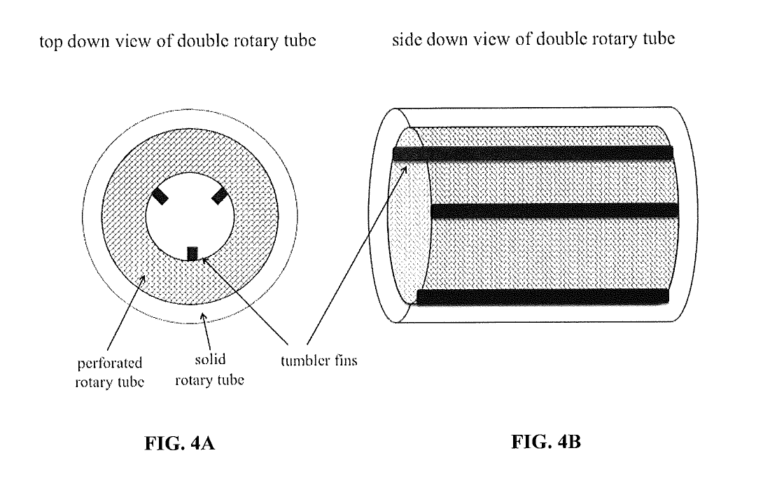

In the system of FIG. 2, for example, separated parts and/or devices can be transported out of rotary kiln 1 to a sorter system, where sorter system and rotary kiln 1 are discrete pieces of equipment. In some embodiments, such as in the system of FIGS. 4A and 4B, for example, a sorter system can be attached to or otherwise integrated within rotary kiln 1, such that the separated parts may remain within rotary kiln 1 as the parts and/or devices are being separated from each other. Such arrangements can be constructed by placing one or more perforated rotary tubes within rotary kiln 1.

In some embodiments, the separated parts and/or devices of varying sizes are at least partially separated from each other according to size in a sorting system comprising, for example, at least one vibrating or non-vibrating screen, which can optionally tilted at an angle to enhance transport of parts and/or devices, which can be used to at least partially separate the incoming parts and/or devices into at least two or more output streams.

The systems and methods described herein can be used to remove components from whole printed circuit boards and/or to remove components from shredded or otherwise deconstructed printed circuit boards. The systems and methods described herein can be used to treat populated and/or unpopulated printed circuit boards.

In certain embodiments, the rotary can be sloped from an incline angle of 1° to 30° from normal to assist transport of the material through the rotary kiln. The residence time for the printed circuit boards in the heating vessel can be adjusted by adjusting the speed of the rotary kiln, so that all of the electronic components detach from the surface of the board by the time the board reaches the exit of the heated vessel. In certain embodiments, the solder melts before the point at which the printed circuit board approaches the silicon brushes.

In general, the components of the system may be fabricated from metal and non-metal materials capable of withstanding the high system temperatures, such as mild steel, stainless steel, nickel alloys, ceramics, and refractory materials.

In some embodiments, an afterburner or other gas abatement unit can be installed at the exit of the rotary kiln in order to prevent pollution.

In use of the parts separation and thermal decomposition of metal-bearing sources described herein, the metal-bearing sources are typically contacted within a rotary kiln for a time of from about 5 min to about 240 minutes, preferably about 5 min to 60 minutes at temperature in a range of from about 100° C. to about 1500° C., more preferably in a range from about 150° C. to about 700° C., and most preferably in a range from about 150° C. to about 600° C. Such contacting times and temperatures are illustrative, and any other suitable time and temperature conditions may be employed that are efficacious to remove the noble metals from the source comprising same.

The kiln of the present invention can be permanently installed at a particular location or can be provided as a portable unit. Often, the kiln system is sufficiently small in size such that it can be placed on a trailer or other movable container so that it can be driven or otherwise delivered to various sources of electronic waste rather than having to ship or transport the waste to the site of a processing plant that has an installation of the kiln.

Those skilled in the art will readily appreciate that all parameters, dimensions, materials, and configurations described herein are meant to be exemplary and that the actual parameters, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein.

### EXAMPLES

The following examples are intended to illustrate certain embodiments of the present invention, but do not exemplify the full scope of the invention.

### Example 1

A mixture comprising printed wire boards extracted from various type smartphones, weighing 1340 grams was introduced into a dual zone rotary tube kiln, model GSL-1600X-R60-II, with a 2.4″ O.D. alumina tube fitted with tumbler fins. The kiln was set to a rotational speed of 7 rpm and a temperature of 230° C., that slightly above the softening temperature of the solder and adhesives contained in the smartphone, in an inert atmosphere such as nitrogen, leading to complete separation of the components from the boards while preventing oxidation of the solder metals.

The resulting separated pieces, specifically 1200 grams of bare boards and a combined 140 grams of metal shields, integrated circuits and other components, exited the rotary kiln and were easily separated according to their size using a vibratory screen, with the bare boards being significantly larger than the ICs and other components. The magnetic pieces contained component mixture was separated from the micro components and integrated circuits using a magnet.

The resulting 94 grams of integrated circuits and components were introduced back into the rotary kiln, containing a predetermined amount and size of steel milling media heated in air to a temperature just above the thermal decomposition temperature of the encapsulant material, ˜385° C., to break the carbon-carbon bonds of the epoxy encapsulant, driving off CO₂ and water vapor. Upon cooling to room temperature, the resulting mass was a 8.8 gram mixture of silicon, metals and powdery silicate slag from the remaining encapsulant material and appeared grey in color. The resulting mixture was determined to have an intrinsic metal value of: Au: 955 ppm; Ag: 5,591 ppm; Pd: 73 ppm; Cu: 193,453 ppm; Ni: 2,530 ppm; Sn: 5048 ppm; Pb: 7557 ppm; Fe: 39,840 ppm; Sb: 6,171 ppm; Al: 46 ppm. The metals were subsequently recovered using conventional techniques such as melting and hydrometallurgy and subsequently separated from the silica-based slag.

### Example 2

A palladium-containing carbon-based catalyst from hydro-processing waste was processed using the present invention. Five kilograms of the catalysts, with metal assay comprising 2010 ppm of palladium with the balance being carbon, was introduced into a rotary kiln and heated to 375° C. in air to convert the carbon to carbon dioxide and water which was subsequently treated in an afterburner located on the exterior of the rotary kiln. The resulting sample weight loss was 99.8%, leaving behind 10.03 grams of palladium in the form of its oxide, for a recovery rate of palladium of 99.8%. The kiln was purged with nitrogen gas to remove any remaining oxygen content and then purged with hydrogen gas at 550° C. to convert the PdOₓ to 99.9% Pd metal.

For the foregoing it is seen that advantages of the present invention include: (i) separation and size reduction of non-metal and/or metal-bearing sources in a high throughput low labor manner; (ii) the process avoids the use of toxic and corrosive chemicals for dissolution of solders, paste, adhesives or heat transfer fluids for separating materials from each other, resulting in zero waste generation; (iii) the constant agitation and milling of the noble metal-bearing carbon-based materials during heating allows for complete thermal oxidation of the noble metal source leaving behind quantitative amounts of exposed noble metal(s), making recovery via conventional hydrometallurgical processes more efficient, while minimizing both chemical and water drag-out waste generation, consuming less chemicals and rinse water in the process, (iv) eliminates noble metal losses observed during grinding and shredding of noble-metal bearing sources, (v) a noble-metal rich concentrate is generated from a device, in which the intrinsic metal value of the device was small compared to the overall device weight, thus making recovery of metals from the concentrate much more efficient and economical as compared to recovery from the whole original device.

In the claims, as well as in the specification herein, all transitional phrases such as “comprising,” “including,” “having,” “containing,” “involving,” and the like are to be understood to be open-ended, and to mean “including but not limited to”.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention.

1. A method for processing electronic waste material that includes electronic components having parts held therein by a binding source comprising one or more of a solder, paste, adhesive or encapsulant, wherein the method comprises:
tumbling the electronic waste material in a chamber that is arranged to advance the electronic waste material therein;
heating the electronic waste material in the chamber at a temperature from 150° C. to 230° C. sufficient to soften the binding source to separate the binding source parts from the electronic components; and
sorting the separated binding source parts from the electronic components to facilitate further processing.

2. (canceled)

3. (canceled)

4. The method of claim 1 further comprising providing the chamber with one or more internal members configured, dimensioned and oriented to facilitate tumbling of the electronic waste material in the chamber or advancement of the electronic waste material through the chamber.

5. (canceled)

6. The method of claim 1 further comprising providing solid, hollow, and/or porous milling media of any geometric shape in the chamber in an amount sufficient to provide or facilitate comminution and separation of the electronic waste material; wherein the milling material has a hardness that is greater than that of the electronic waste material.

7. The method of claim 1 wherein the sorting the separated parts in the chamber is achieved by passing the separate parts through a perforated tube located within an outer tube in the chamber, wherein the perforations of the inner tube are configured to allow smaller sized parts to pass therethough to provide size sorting of parts before they exit the chamber.

8. The method of claim 1 wherein the sorting the separated parts is achieved by providing a vibrating mesh screen that receives the processed material that exits the chamber and sorts that material into various size fractions.

9. The method of claim 1 wherein electronic waste material includes printed circuit boards, catalysts and/or solar panels, the binding source includes adhesives, glues, cements, mucilage, pastes, carbon, solders or organic resins and the processing is achieved by thermally decomposing organic and/or inorganic compositions of the electronic waste material.

10. (canceled)

11. The method of claim 9, which further comprises recovering metals from the electronic waste material and subjecting the recovered metals to additional purification processes.

12. The method of claim 1, further comprises subjecting the separated parts to a liquid or gaseous chemical process for recovering noble and/or non-noble metals.

13. (canceled)

14. The method of claim 1, wherein the chamber is a direct- or indirect-heated rotary kiln that is tilted and rotated to advance the electronic waste material therethrough its entry at one end to an exit at the other end for processing of the electronic waste material therein.

15. (canceled)

16. A method for processing electronic waste material comprising electronic components and a binding source comprising one or more of a solder, paste, adhesive or encapsulant, wherein the method comprises:
(a) tumbling the electronic waste material in a chamber that is arranged to advance the electronic waste material therein;
(b) heating the electronic waste material in the chamber at a temperature sufficient to soften the binding source to separate the electronic components from the binding source; and
(c) sorting the separated electronic components and binding source;
wherein the heating is to a temperature to soften the binding source.

17. A method for recovery of electronic components from electronic waste material comprising the electronic components adhered onto circuit boards comprising a binding source, wherein the method comprises:
(a) tumbling the electronic waste material in a chamber that is arranged to advance the electronic waste material therein;
(b) heating the electronic waste material in the chamber at a temperature sufficient to soften the binding source to separate the electronic components from the circuit boards; and
(c) sorting the separated electronic components and circuit boards,
wherein the separation of the electronic components from the circuit boards is achieved by thermo-mechanical energy and the separated electronic components are in an undamaged condition.

18. A method for recovery of electronic components from electronic waste material comprising the electronic components adhered onto circuit boards comprising a binding source, the method consisting essentially of:
(a) tumbling the electronic waste material in a chamber that is arranged to advance the electronic waste material therein;
(b) heating the electronic waste material in the chamber at a temperature sufficient to soften the binding source to separate the electronic components from the circuit boards; and
(c) sorting the separated electronic components and circuit boards.

19. The method of claim 1, wherein the chamber is within a rotary kiln

20. The method of claim 1, wherein the sorting is achieved within the chamber.

21. The method of claim 1, wherein the separated electronic components are recovered in working condition.

22. The method of claim 1, wherein the separated electronic components are in an undamaged condition.

23. The method of claim 17, wherein said separated electronic components and circuit boards can be sorted by size.

24. The method of claim 1, wherein said heating is for a time ranging from 5 minutes to 60 minutes.

25. The method of claim 16, wherein the heating is to a temperature ranging from 150° C. to 230° C. to soften the binding source.

26. The method of claim 1, wherein the heating occurs in an inert atmosphere.

27. The method of claim 1, wherein the chamber is configured to be placed on a portable trailer or movable container.

28. The method of claim 1, wherein the chamber is on a portable trailer or a movable container and the tumbling occurs on the portable trailer or movable container.

29. The method of claim 17, wherein said method leads to complete separation of the electronic components and circuit boards.

30. The method of claim 17, wherein said recovery is achieved in a system consisting essentially of said chamber.
